(19) United States
(12) Patent Application Publication
(10) Pub. No.: US 2025/0351431 A1
(43) Pub. Date: Nov. 13, 2025

(54) SILICON-CARBIDE METAL-OXIDE-SEMICONDUCTOR FIELD-EFFECT TRANSISTOR (MOSFET) WITH SUPERJUNCTION AND BIFURCATED SOURCE

(71) Applicant: Navitas Semiconductor Limited, Dublin (IE)

(72) Inventor: Siddarth SUNDARESAN, Torrance, CA (US)

(73) Assignee: Navitas Semiconductor Limited, Dublin (IE)

(21) Appl. No.: 19/200,482

(22) Filed: May 6, 2025

Related U.S. Application Data
(60) Provisional application No. 63/643,749, filed on May 7, 2024.

(51) Int. Cl. H10D 30/66; H10D 30/01; H10D 62/10; H10D 62/832; H10D 64/23; H10D 64/27; H10D 64/66; H10D 84/00

(52) U.S. Cl. CPC H10D 30/668; H10D 30/0295; H10D 30/0297; H10D 62/107; H10D 62/124; H10D 62/8325; H10D 64/256; H10D 64/514; H10D 64/518; H10D 64/661; H10D 84/143

(57) ABSTRACT

An embodiment of a SiC transistor includes a SiC substrate and a layer of metallization, which forms a drain terminal of the transistor. The SiC substrate includes a first horizontal N-doped region disposed above the layer of metallization, a second horizontal region disposed above the first horizontal region and including an N-doped region beside a P-doped region, a gate conductor disposed above the N-doped region, an N-doped source disposed above the P-doped region, and a source metal that bisects the source and that is electrically coupled to the P-doped region and the source. As compared to a SiC power transistor lacking the second generally horizontal region or the bisected source, an embodiment of the SiC power transistor can have, for a given maximum-blocking-voltage rating, a thinner substrate region, and, therefore, a lower RdsON over a range of transistor-operating temperatures (e.g., at room temperature and at higher temperatures).

### CROSS-REFERENCES TO OTHER APPLICATIONS

This patent application claims priority to U.S. provisional patent application Ser. No. 63/643,749, for “SILICON CARBIDE PLANAR TRENCH METAL-OXIDE-SEMICONDUCTOR FIELD EFFECT TRANSISTOR (MOSFET)” filed on May 7, 2024, which is hereby incorporated by reference in its entirety for all purposes.

### FIELD

The disclosed embodiments relate generally to a transistor device. More particularly, the disclosed embodiments relate to a silicon-carbide (SiC) transistor device comprising a bifurcated source and a superjunction region.

### BACKGROUND

A SiC power device, e.g., a power transistor, can be employed in a high-power, high-voltage, or high-temperature environment where the resistance of the device from drain to source (RdsON) can be an important figure of merit over the temperature range of device operation. In a typical SiC-based power device, there are multiple contributors to RdsON including the channel, the drift region, the junction-gate field-effect transistor (JFET) region, and the substrate region. Because the resistance of the substrate region can increase with temperature, decreasing the thickness of the substrate region can result in a lower RdsON at both room-temperature and at higher operating temperatures. However, reducing the substrate thickness also can increase a respective magnitude of one or more electric fields within the device (e.g., when the device is subjected to a relatively high voltage while the device is in an off-state), where such an electric-field increase may result in failure of the device. That is, although reducing the substrate thickness may decrease a SiC power transistor's RdsON (typically desirable), it also may decrease transistor's maximum blocking-voltage rating (typically undesirable).

New SiC power device structures and/or manufacturing processes are needed to produce SiC power devices that enable reductions in the substrate thickness while maintaining the transistor's maximum blocking-voltage rating.

### SUMMARY

In some embodiments a silicon-carbide (SiC) transistor includes a SiC substrate and a layer of metallization, which forms a drain terminal of the transistor. The SiC substrate includes a first generally horizontal region disposed above the layer of metallization and including an N-type dopant, a second generally horizontal region disposed above the first generally horizontal region and including an N-type doped region beside a P-type doped region, a gate structure including a gate conductor disposed above the N-type doped region, a source disposed above the P-type doped region and including an N-type dopant, and a source metal that bisects the source and that is electrically coupled to the P-type doped region and the source. Such an embodiment of a SiC power transistor, as compared to a SiC power transistor lacking the second generally horizontal region or the bisected source, can have, for a given maximum-blocking-voltage rating, a thinner substrate region, and, therefore, a lower RdsON over a range of transistor-operating temperatures (e.g., at room temperature and at higher temperatures).

In some embodiments the second generally horizontal region includes a plurality of alternating N-type doped regions and P-type doped regions.

In some embodiments the SiC transistor includes a P-well disposed above the second generally horizontal region, and the source is disposed in the P-well.

In some embodiments the gate structure includes polysilicon and bisects the P-well.

In some embodiments the gate structure has a T-shape and includes a vertical region that bisects the P-well into at least two regions and a horizontal region integral with the vertical region and disposed above the at least two regions of the P-well.

In some embodiments a silicon-carbide (SiC) transistor includes a layer of drain metal and a SiC-based substrate disposed above the layer of drain metal and including a first planar region including an N-type dopant, a second planar region disposed above the first planar region and including alternating N-type doped regions and P-type doped regions arranged in a horizontal repeating pattern, a plurality of P-well regions each disposed above a respective one of the N-type doped regions, a plurality of source regions including an N-type dopant and each disposed above a respective one of the P-type doped regions, and a layer of source metal bisecting each of the plurality of source regions.

In some embodiments at least some of the plurality of source regions are each disposed above a respective one of the plurality of P-well regions.

In at least some embodiments, the SiC-based transistor includes at least one polysilicon gate structure each of which bifurcates a respective P-well region of the plurality of P-well regions.

In some embodiments each of the at least one polysilicon gate structure has a respective T-shaped cross-section including a respective vertical portion that bifurcates the respective P-well region and a respective horizontal portion disposed over portions of the respective bifurcated P-well region.

In some embodiments the drain metal includes multiple layers of metal.

In some embodiments, a method for forming a silicon-carbide (SiC) transistor includes forming, over a first side of a first generally horizontal N-type region of a SiC substrate, a metal drain terminal, forming, over a second side of the first generally horizontal N-type region that is opposite to the first side, a second generally horizontal region including a laterally arranged first N-doped region and first P-doped region, forming, over the P-doped region, a source including an N-type dopant, forming, through the source, a source trench that exposes the P-doped region and vertical sides of the source, and forming, in the source trench, a source metal that electrically contacts the P-type doped region and the vertical sides of the source.

In some embodiments the method includes forming the first generally horizontal N-type region of the SiC substrate.

In some embodiments the method includes forming a gate conductor over the N-doped region.

In some embodiments forming the second generally horizontal region includes forming N-doped regions including the N-doped region and forming P-doped regions that alternate with the N-doped regions.

In some embodiments, the method includes forming a P-well over the second generally horizontal region and forming the source includes forming the source in the P-well.

In some embodiments the method includes forming, through the P-well, a gate trench that extends into the N-doped region, and forming, in the gate trench, a polysilicon gate that extends laterally over the P-well.

In some embodiments the method includes forming a T-shaped polysilicon gate having a vertical region that bisects the P-well into at least two regions and a horizontal region integral with the vertical region and over the at least two regions of the P-well.

In some embodiments the method includes forming a second N-doped region between the first N-doped region and a bottom of the gate trench.

In some embodiments the method includes forming a second P-doped region between the first P-doped region and a bottom of the source trench.

In some embodiments the method includes forming a second P-doped region in the second N-doped region at a bottom of the gate trench.

### BRIEF DESCRIPTION OF THE DRAWINGS

FIG. 1 is a schematic symbol for a SiC N-channel transistor, such as a power transistor, according to an embodiment.

FIG. 2 is a planar view of a SiC die having at least one SiC transistor partially formed therein and partially formed thereon, according to an embodiment.

FIG. 3 is a partial simplified cross-section, taken along lines 3-3 of FIG. 2, of a SiC N-channel transistor with a superjunction region, a T-shaped gate structure, and a bifurcated source region.

FIG. 4 is a cross-section of another embodiment of a SiC N-channel transistor with a superjunction region having multiple sinker regions, a T-shaped gate structure, and bifurcated source regions, according to an embodiment.

FIG. 5 is a cross-section of another embodiment of a SiC n-channel transistor with a superjunction region having multiple sinker regions, a T-shaped gate structure, bifurcated source regions, and an N-doped region of the superjunction region more heavily doped adjacent to the gate structure.

FIG. 6 is a flow diagram of a process for forming a SiC transistor, such as the transistor 200 of FIGS. 2-3, transistor 400 of FIG. 4, or transistor 500 of FIG. 5, having a superjunction region and a bifurcated source, according to an embodiment.

FIG. 7 is a flow diagram of a process for forming a SiC transistor, such as the transistor 200 of FIGS. 2-3, transistor 400 of FIG. 4, or transistor 500 of FIG. 5, having a T-shaped gate structure, according to an embodiment.

FIG. 8 is a cross section of a SiC wafer having a substrate and a drift region and usable to form a SiC transistor such as the transistor 200 of FIGS. 2-3, transistor 400 of FIG. 4, or transistor 500 of FIG. 5, according to an embodiment.

FIG. 9 is the cross section of the SiC wafer of FIG. 8 including a well formed in the drift region, according to an embodiment.

FIG. 10 is the cross section of the SiC wafer of FIG. 9 including source regions formed in the well, according to an embodiment.

FIG. 11 is the cross section of the SiC wafer of FIG. 10 including a sinker formed beneath the source regions and the well, according to an embodiment.

FIG. 12 is the cross section of the SiC wafer of FIG. 11 including source trenches (only two source trenches shown in FIG. 12) formed in the source regions, gate trenches (only one gate trench shown in FIG. 12) formed in the well, and a superjunction region formed beneath the well, according to an embodiment.

FIG. 13 is the cross section of the SiC wafer of FIG. 12 including T-shaped gate structures formed in the gate trenches and extending laterally over regions of the well adjacent to the gate trenches, according to an embodiment.

FIG. 14 is the cross section of the SiC wafer of FIG. 13 including a source contact (e.g., metal) formed in the source trenches and over the T-shaped gate structures and a drain contact (e.g., metal) is formed on a side of the SiC wafer opposite to the side over which the source contact is formed, according to an embodiment

FIG. 15 is a schematic diagram of a circuit (e.g., a buck converter) that incorporates a SiC transistor, such as one of the SiC transistors 200, 400, or 500 of FIGS. 2-5, according to an embodiment.

### DETAILED DESCRIPTION

In the following description, various embodiments will be described. For purposes of explanation, specific configurations and details are set forth to provide a thorough understanding of the embodiments. However, it will also be apparent to one skilled in the art that the embodiments may be practiced without some or all of the specific details. Furthermore, well-known features may be omitted or simplified in order not to obscure an embodiment being described.

Some embodiments of the present disclosure relate to a SiC-based transistor that employs a superjunction region disposed beneath a planar-trench MOSFET channel region. Some embodiments relate to a SiC-based transistor that employs a bifurcated source and some embodiments relate to a SiC-based transistor that includes both a superjunction region and a bifurcated source. While the present disclosure can be useful for a wide variety of configurations, some embodiments of the disclosure are particularly useful for a SiC-based transistor with reduced RdsON that operates at higher-power, higher-voltage, or higher-temperature conditions compared to a conventional transistor, as described below.

For example, in an embodiment, the introduction of a superjunction region within the substrate of the SiC-based transistor may enable a reduction in a thickness of a substrate region without reducing the ability of the transistor to withstand high positive bias voltages (that is, without reducing the transistor's blocking voltage compared to a similar transistor having a thicker substrate region but lacking a superjunction region). More specifically, the structure of the superjunction region may employ a series of alternating P-doped regions (also called “P regions”) and N-doped regions (also called “N regions) that together form a plurality of PN junctions therebetween. The PN junctions may form one or more depletion zones while the transistor is positively biased (e.g., a positive bias voltage is applied to the drain of an N-channel device while the source is grounded) while in a non-conductive state, thus resulting in decreased electric fields within the transistor. Thus, an embodiment of the superjunction region can allow a reduction in the thickness of the substrate region with little or no reduction of the withstanding (blocking) voltage of the device, and the reduction in the substrate-region thickness can result in lower RdsON at both room-temperature and higher-temperatures as compared to a transistor having no superjunction region. The addition of a bifurcated source can improve the voltage-blocking ability of the superjunction region by allowing the superjunction region to be formed deeper (further beneath the source and well) as compared to a transistor without a bifurcated source.

Further, the employment of a part-planar, part-trench MOSFET channel in an embodiment of the SiC-based transistor may function cooperatively with the superjunction region to enable further reductions in RdsON. More specifically, a SiC MOS-based transistor with a planar-gate channel structure can exhibit relatively low channel mobility, which can be a significant contributor to RdsON. But the employment of a planar-trench structure, which can include a T-shaped gate structure, can enable the formation of relatively large dual L-shaped channels directly above each N region of the superjunction region, thereby increasing an area of the channel and reducing RdsON. In SiC, the channel mobility along the trench sidewalls (e.g., a-face (typically preferred) or m-face sidewalls) can be a factor of 1.5 to 3 times more than the channel mobility along a C-face (e.g., a planar surface approximately perpendicular to the trench sidewalls). Thus, the combination of a planar-trench MOSFET channel region with a superjunction region can enable a SiC-based transistor with improved room-temperature and high-temperature RdsON performance (e.g., reduced room-and high-temperature RdsON as compared to a SiC transistor with only a planar channel region or only a vertical-trench channel region), as described in more detail below.

To better appreciate the features and aspects of SiC-based transistors with superjunction and planar-trench regions and source trench regions according to the present disclosure, further context for the disclosure is provided in the following section by discussing one particular implementation of a SiC-based transistor according to one or more embodiments of the present disclosure. These one or more embodiments are for example only, and other geometries, arrangement of structures, and configurations can be employed in other transistor devices, and are within the scope of this disclosure.

Several illustrative embodiments will now be described with respect to the accompanying drawings, which form a part hereof. The ensuing description provides embodiment(s) only and is not intended to limit the scope, applicability, or configuration of the disclosure. Rather, the ensuing description of the embodiment(s) provides those skilled in the art with an enabling description for implementing one or more embodiments. It is understood that various changes may be made in the function and arrangement of elements without departing from the spirit and scope of this disclosure. In the following description, for the purposes of explanation, specific details are set forth to provide a thorough understanding of certain embodiments. However, it will be apparent that various embodiments may be practiced without these specific details. The figures and description are not intended to be restrictive. The word “example” or “exemplary” is used herein to mean “serving as an example, instance, or illustration.” Any embodiment or design described herein as “exemplary” or as an “example” is not necessarily to be construed as preferred or advantageous over other embodiments or designs.

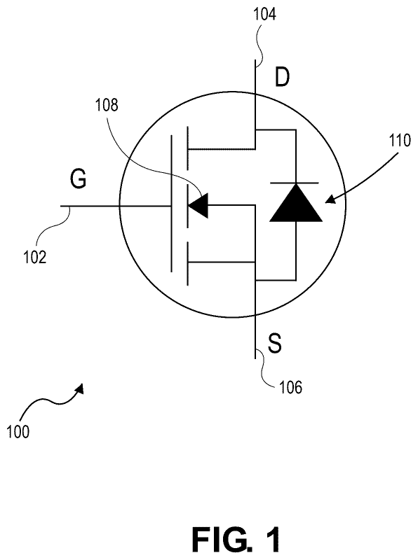

FIG. 1 is a conventional schematic symbol for a SiC enhancement-mode N-channel transistor 100. The nodes 102 (G), 104 (D), and 106 (S) represent the transistor gate, drain, and source, respectively. The substrate arrow 108 indicates that the SiC transistor is an N-channel device in which most, or all, of the charge carriers while the transistor is operating a conductive mode are electrons. As further shown in FIG. 1, the SiC transistor 100 includes a body diode 110.

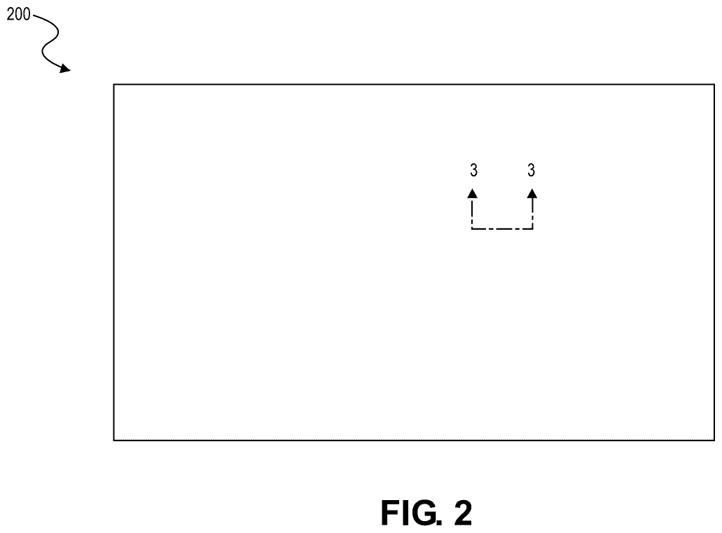

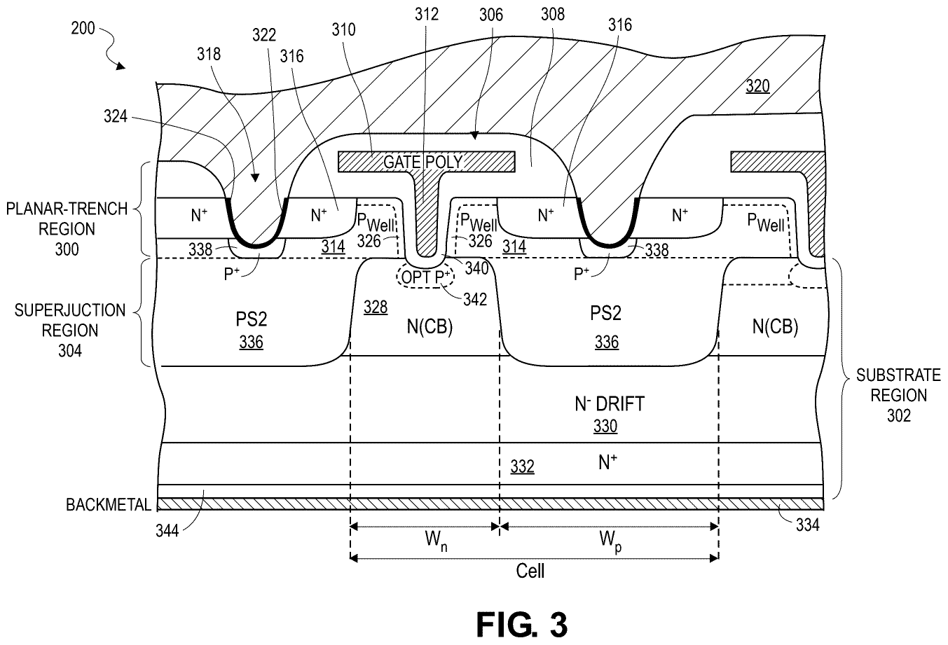

FIG. 2 depicts a simplified plan view of a SiC-based transistor 200 that includes a planar-trench MOSFET channel region that operates in conjunction with a superjunction region, and a source trench, according to some embodiments of the present application. A simplified cross-section of a portion of the SiC-based transistor 200 taken along lines 3-3 is shown in FIG. 3.

FIG. 3 depicts a simplified cross-sectional view of a portion of the SiC-based transistor 200 represented by the schematic symbol in FIG. 1 and shown in FIG. 2, according to an embodiment. As shown in FIG. 3, the SiC-based transistor 200 includes a planar-trench MOSFET channel region 300 disposed in or on a substrate region 302. A portion of the substrate region 302 is a superjunction region 304, which is positioned below the planar-trench channel region 300. The planar-trench MOSFET channel region 300 may operate cooperatively with the superjunction region 304 to reduce the RdsON of the SiC-based transistor 200 (as compared to a similar SiC transistor without the superjunction region 304) while enabling the transistor to operate at relatively high voltages and high temperatures, as described in more detail below.

The planar-trench channel region 300 may include a T-shaped polysilicon gate structure 306, which is enclosed by one or more dielectric materials 308. The T-shaped gate structure 306 may have a planar (horizontal) portion 310 coupled to a trench (vertical) portion 312, which extends through the planar-trench channel region 300 into the superjunction region 304. Adjacent the planar 310 and trench 312 portions of the T-shaped gate structure 306 are P-well (PW) regions 314, which are P-doped. Adjacent to each P-well region 314 may be a respective N+ source region 316, which is N-doped; the planar 310 portion of the T-shaped gate structure 306 can overlap each adjacent portion of the source regions 316 by, for example, 150-200 nanometers (nm). Adjacent to each N+ source region 316 is a respective source trench region 318 filled with a source conductor, such as a source metal, 320; the source metal is in ohmic contact with a respective vertical sidewall 322 of each of the N+ source regions—although the sidewalls are described as “vertical,” they may be curved or otherwise may not be a straight line at +90°. A respective optional silicide layer 324 may be formed between each of the N+ source regions 316 and the source metal 320 to reduce electrical resistance between the source region and the source metal. Due to the presence of the source trench region 318, the source regions 316 can be considered to form a “bisected” or a “bifurcated” source. Upon application of a negative bias voltage between the source metal 320 and the T-shaped gate structure 306 (i.e., a positive bias voltage from the gate to the source metal), dual L-shaped depletion regions (see dashed lines in FIG. 3), also known as “channel regions,” 326 form in each P-well region 314 adjacent the gate structure 306. The dual L-shaped channel regions 326 are relatively large (e.g., wide in a dimension perpendicular to the page or long in a dimension into and out of the page) and enable electrons to freely flow from the source metal 306, through the N+ source regions 316, along the channel regions 326, down into and through N-doped charge-balance (CB) regions 328 of the superjunction structure 304, into and through an N− drift region 330 and an N+ substrate 332, to a drain (back) metal 334, as described below.

Still referring to FIG. 3, each T-shaped gate structure 306 is aligned with a respective N-doped region 328 of the superjunction region/structure 304, which includes alternating P-doped regions (P-doped sinker regions PS2) 336 and the N-doped charge-balance regions 328. While a positive gate-to-source bias voltage is applied across the gate 306 and source 316, the N charge-balance regions 328 of the superjunction structure 304 enable current to flow from the channel regions 326, through the charge-balance regions, down to the N-drift region 330 of the substrate region 302, through the N+ substrate 332 of the substrate region, and to the backmetal layer 334, which is a drain terminal of the SiC-based transistor 200.

When the SiC-based transistor 200 is in a blocking configuration caused by a positive bias voltage applied across the drain 334 and the source 316 (e.g., the source is grounded and a positive voltage is applied to the drain) and a gate-to-source voltage that is too low to support conduction from the drain to source of the transistor, the superjunction structure/region 304 forms depletion regions at each PN junction of the PS2 regions 336 and the adjacent N charge-balance regions 328 and adjacent N− drift regions 330. With increasing drain-to-source bias voltage, the depletion regions grow from each PN junction until the entire volume of each N region 328 of the superjunction structure 304 is depleted, thereby providing an increased withstanding (e.g., blocking) voltage of the transistor 200 as compared to a similar transistor lacking the superjunction structure. Thus, while the transistor 200 is in the blocking configuration, i.e., is operating in a blocking mode, the superjunction structure 304 enables a decrease in one or more electric fields within the device (e.g., at the junctions of the regions of the P-well 314 and the N⁻ drift region 330 or at the junctions of the regions of the P-well and the regions of the N⁺ source 316) such that the SiC-based transistor 200 can withstand relatively high drain-to-source voltages even with a relatively thin substrate region 302. That is, for a given rated blocking-voltage, the superjunction region 304 allows the transistor 200 to have a thinner substrate region 302 than a similar SiC transistor that lacks the superjunction region. And the thinner the substrate region 302, the lower RdsON at higher operating temperatures of the transistor 200, and even at and lower operating temperatures of the transistor. Furthermore, as stated above, the L-shaped channels 326 can further lower the RdsON of the transistor 200.

Still referring to FIG. 3, one full cell of the transistor 200 is shown as well as two partial cells. A pitch range for each cell can be between, for example, 2 μm-5 μm measured from the center of the vertical gate segment 312 to the center of an immediately adjacent vertical gate segment. The layers of the SiC-based transistor 200 can have a variety of doping levels. For example, in some embodiments (such as the embodiment described above) the layers/regions can include the N^{′} substrate 332, the N⁻ drift layer 330, the superjunction region 304, the P-well layer 314, the bifurcated N⁺ source region 316, P⁺ source-well contact regions 338, a gate-polysilicon (or metal) layer 306, and a source-metal layer 320. The SiC-based transistor 200 also can include gate trenches 340 and source trenches 318. In some examples, the SiC-based transistor device 200 can include multiple SiC-based double-implanted metal-oxide semiconductor field-effect transistors (DMOSFETs). In some embodiments the N⁺ substrate 332 can be relatively highly doped with a doping concentration of approximately, e.g., 1E19 cm⁻³, and can have a thickness in any suitable range in, for example, microns (μm). In further embodiments, the N⁻ drift layer 330 can be epitaxially grown from the substrate 332 and have a doping concentration in a range of, e.g., 1E15 cm⁻³-1E16 cm⁻³ and a thickness in a range of, e.g., 1 μm-300 μm.

The P-well 314 layer can be formed by depositing a first hard mask that is patterned and then performing an implantation or epitaxial growth step. The P-type implantation step can be performed using boron, aluminum or other suitable dopant, and may have doping levels, for example, in a range of e.g., 1E16-1E18 cm⁻³.

Before the first hard mask is removed, a second hard mask can be deposited and patterned. The second hard mask can be deposited by a chemical-vapor-deposition-(CVD)-deposited layer of silicon oxide, silicon nitride, silicon oxynitride, or a metallic layer such as nickel, with a thickness ranging from 50 nanometers (nm) to 5 microns (μm) on top of the patterned first hard mask. In some examples, an anisotropic etch can form a sidewall spacer to help define the N⁺ source regions 316, which can have a smaller combined footprint than the P-well 314 layer. That is, the N⁺ source 316 can be formed in the P-well 314, which can extend to a greater depth than the N⁺ source regions 316. For example, the P-well 314 layer can have a depth in any suitable range, and the N+ source 316 can have depths in any suitable range.

The regions 316 of the N⁺ source can be formed via implantation or epitaxial regrowth of N-type (N⁺) impurities using, for example, nitrogen or phosphorous. The N⁺ source regions 316 can be formed in a self-aligned fashion with the P-well 314 layer, and can be heavily doped in the range of, e.g., 5E18-1E20 cm⁻³.

Below both the N⁺ source regions 316 and the P-well 314 layer, the superjunction region 304 can include alternating P-type (e.g., P-doped) regions 336 and N-type (e.g., N-doped) charge-balance regions 328 arranged horizontally. The P-type regions 336 in the superjunction-region 304 layer can be referred to as P-type sinker #2 layers, PS #2 regions, or PS2 regions 336, which may be formed at a same time, or during a same step, as the N⁺ source regions 316. The PS2 regions 336 may be formed using e.g., an aluminum or boron dopant and placed under the N⁺ source regions 328 at a greater depth than the P-well 314 layer (the source trenches 318 can facilitate implanting the PS2 regions at a greater depth than the P-well). The PS2 regions 336 may be formed using a P-type impurity, e.g., boron, which can have a higher ion-implantation range as compared to aluminum in SiC. Doping levels of the PS2 regions 336 can be in a range, for example, of 1E16-5E17. And the PS2 regions 336 each can have a width of wₚ, which can be in any suitable range.

The N-doped charge-balance regions 328 of the superjunction-region 304 layer can be formed in a similar manner as the N⁺ source regions 316, e.g., via implantation or epitaxial regrowth of N-type (N⁺) impurities using nitrogen or phosphorous (the gate trenches 340 can facilitate the implantation of the N-doped regions 328 at a relatively deep depth). The N-type regions 328 of the superjunction 304 layer can be moderately doped in a range of, e.g., 1E16-5E16 cm⁻³. Widths wₙ of each N-doped region 328 can be in any suitable range. A selection of doping level for the N-doped regions 328 can be based on a charge-balancing condition (e.g., balancing of activated integrated charge across the N-type regions 328) with the PS2 regions 336 (e.g., with the activated integrated charge across the PS2 regions) of the superjunction 304 layer. The charge-balancing condition can be described by an expression: Nₚwₚ=Nₙwₙ, where Nₚdenotes the doping level of the PS2 regions 336 and Nₙ denotes the doping level of the N-type regions 328 of the superjunction 304.

Balancing of activated charge in the PS2 regions 336 and in the N-doped regions 328 can depend on the doping levels or dimensions of the aforementioned regions because ionization (e.g., the process by which an atom or molecule gains or loses electrons and, therefore, by which a semiconductor region conducts current) can be different in P-doped regions and N-doped regions. Thus, in an embodiment, if the widths wₚ and wₙ are equivalent (wₚ=wₙ), then the doping level of the N-doped regions 328 of the superjunction 304 can match the doping level of the PS2 region 336 (Nₙ=Nₚ) to provide a suitable level of charge balancing. Alternatively, if the widths wₚ and wₙ are different (e.g., wₚ=3wₙ), then the doping level of the N-doped charge-balance regions 328 can be selected e.g., Nₙ=3Nₚ, so that there is charge balancing between the PS2 336 regions and the corresponding N charge-balancing regions 328. Furthermore, in some examples, doping levels of the PS2 regions 336 may vary with depth. In such examples, the doping levels of the N-doped charge-balancing regions 328 of the superjunction 304 may vary with depth as well, such that a charge-balancing condition can be met at every depth location of the superjunction 304.

The source trench 318 can be formed by lithographic patterning and then by etching completely through the N⁺ source 316 layer into the underlying P-well 314 layer. Although source trenches 318 shown in FIG. 3 include a roughly 90° sidewall angle, the sidewall angle of the source trenches may be more gradual or less steep (e.g., between 60°-90°. With a same hard mask that was used to form the source trench 318, a P-type implantation step can be performed to create P⁺ source-bulk contact regions 338. If this P-type-dopant implantation step involves aluminum, then the P⁺ source-bulk contact region 338 can be formed with implant doses ranging from 1E13 cm⁻² to 1E16 cm⁻². If the P-type-dopant implantation step involves boron, then the P⁺ source-bulk contact region 338 also can be formed using implant doses ranging from 1E13 cm⁻²to 1E16 cm⁻². Or the P⁺ source-bulk contact region 338 can be heavily doped, e.g., in a range of 1E17-1E19 cm⁻³. And the P⁺ source-bulk contact region 338 can extend through the P-well region 314 and terminate at a boundary with, on, or in, an underlying PS2 region 336.

Similar to the formation of the source trenches 318, the gate trenches 340 can be formed by lithographic patterning or etching completely through the underlying P-well 314 layer. Although gate trenches 340 shown in FIG. 3 include a roughly 90° sidewall angle, the sidewall angle of the gate trenches may be shallower (e.g., between 60°-90°). With a same hard mask that was used to make the gate trenches 340, an N-type-dopant can be implanted to create the N-doped region 328, and a P-type-dopant implantation step can be performed to create an optional P⁺ gate buffer region 342. In some examples, the P⁺ gate buffer region 342 can be formed under similar conditions as the P⁺ source-bulk contact region 338 as described above, and in some examples, the optional P⁺ gate buffer region can be formed in a single fabrication step with the P⁺ source-bulk contact region. A function of the P⁺ gate buffer region 342 can be to shield the bottom of the gate trench 340 from a relatively high-magnitude electric field that may otherwise be generated at a junction of the N-doped region 328 and the bottom of the gate trench (the buffer region 342 effectively shifts this relatively high electric field away from the bottom of the gate trench by forming a depletion region while the gate-source voltage is at a high-enough positive voltage to render the channel 326 conductive). The P⁺ source-bulk contact region 338 can be heavily doped (e.g., 1E17-1E19 cm⁻³). A depth of the P⁺ gate buffer region 342 can extend past the adjacent P-well 314 regions and terminate in, or at a boundary with, an underlying N-doped region 328 of the superjunction 304.

As described above, an ohmic contact 324, such as Ni-silicide, can be formed on an exposed surface of the SiC wafer; for example, the ohmic contact can be made to the N+ source regions 316 along the etched sidewalls 322 of the source trench 318. A gate polysilicon layer can be embedded in the source 320 metal layer and insulated from an upper surface of the SiC wafter in the planar-trench region 300 via one or more dielectric materials that together form the gate insulator 308. Under certain operating conditions, a current formed from majority-carrier electrons of the N+ source regions 316 can flow from the N+ source regions, along respective horizontal portions of channels 326 formed along a boundary between the P-well regions 314 and a surface of the SiC wafer, and along respective vertical potions of the channels formed along boundaries between the P-well regions and the gate trenches 340. That is, the formed (by electrical inversion) channels 326 can have an L-shape due to the presence of the gate trench 340 and the vertical portion 312 of the gate 306. The current can flow from the channels 326 into the respective underlying N-doped charge-balance regions 328 of the superconductor region 304, through the N⁻ drift layer 330, through the N⁺ substrate 332 and an optional silicide/contact layer 344, and to the drain metal 334.

A polysilicon gate metal layer may be deposited within the gate trench 340 (e.g., entrenched) using PECVD, LPCVD or one or more other suitable processes to form the gate 306. The polysilicon layer may be degenerately doped (to exhibit a conductivity level comparable to a metal) using boron or phosphorus, either in-situ or in a subsequent step. In-situ doping may be performed by an addition of a phosphine (PH3) precursor to a polysilicon-deposition chemistry. Post-deposition doping of polysilicon may be performed by depositing a layer of phosphoryl chloride (POCL₃) followed by a drive-in step at temperatures ranging from 700-900° C. Alternatively, post-deposition P-type doping may be accomplished either by performing a high-dose boron implant into the polysilicon or by using a diborine gas-phase doping. A gate-metal hard mask can be deposited and patterned. The polysilicon gate layer can be etched using the patterned gate-metal hard mask, which can be removed after etching. A voltage bias between the gate and the source can initiate and control a formation of the channel 326 along the P-well 314 layer boundary with the gate insulator 308 (horizontal channel portion) and the gate trench 340 (vertical channel portion). Further details regarding the planar MOSFET fabrication process can be found in U.S. Pat. Nos. 11,075,277 or 10,916,632, both of which are herein incorporated by reference.

The gate 306 having a horizontal portion 310 and a vertical portion 312 can increase the conductivity of the channel 326, and, therefore, can contribute to a reduction in the RdsON of the transistor 200, because the field-effect mobility of carriers (electrons in this embodiment) in the vertical portion of the channel can be significantly higher than the field-effect mobility of carriers in the horizontal portion of the channel due to, e.g., of the crystalline structure in a vertical plane of a SiC wafer versus the crystalline structure in a horizontal plane of a SiC wafer. For example, the field-effect mobility of electrons in the vertical portion of the channel 326 can be, e.g., 80 cm²/V·s versus a field-effect mobility of electrons in the horizontal portion of the channel of only, e.g., 26 cm²/V·s. Consequently, at least a portion of the channel 326 being along a vertical side of the P-well 314 can increase the overall electron mobility of the channel, and, therefore, can decrease the overall RdsON of the transistor 200 as compared to the RdsON of a transistor having a channel with only a lateral portion. And although the portion of the gate insulator 308 along the vertical portion of the channel 326 may accumulate more trapped charges over time than the portion of the gate insulator along the horizontal portion of the channel, the increase in electron mobility within the vertical portion of channel typically outweighs the chances of any degradation, over time, in the performance of the transistor 200 caused by these trapped charges. In an embodiment, the length of the horizontal portion of the channel 326 can be 0.5 μm or less, and the length of the vertical portion of the channel can be longer, for example in a range of 0.5 μm-1.5 μm.

In some embodiments the polysilicon-metal gates 306 can be insulated from the P-well 314 regions by an oxide layer and can be insulated from the source metal 320 by an inter-layer dielectric (ILD), where the oxide layer (e.g., the portion of the gate insulator 306 lining the gate trench 340 and disposed between the source regions 316 and P-well regions 314 and the horizontal portion 310 of the gate) and the ILD (the remaining portion of the gate insulator 306) together form the gate insulator 306. In some examples, the gate-oxide layer can be formed by thermal oxidation, CVD, or one or more other suitable processes. The gate-oxide layer can be any suitable dielectric layer, such as silicon dioxide, silicon nitride, or silicon oxynitride. A thickness of the gate oxide can range from 10 nm to 100 nm. Either dry or wet thermal oxidation can be used for growth of the gate oxide. Alternatively, plasma-enhanced chemical-vapor deposition (PECVD), or low-pressure chemical-vapor deposition (LPCVD), can be used for depositing the gate oxide. In some examples, the ILD layer can be silicon dioxide, silicon nitride, silicon oxynitride layers, or a combination of multilayers, where the total thickness of the ILD layer can be 50 nm to 1000 nm. And the ILD layer and the gate-oxide layer can be etched and patterned using any suitable process.

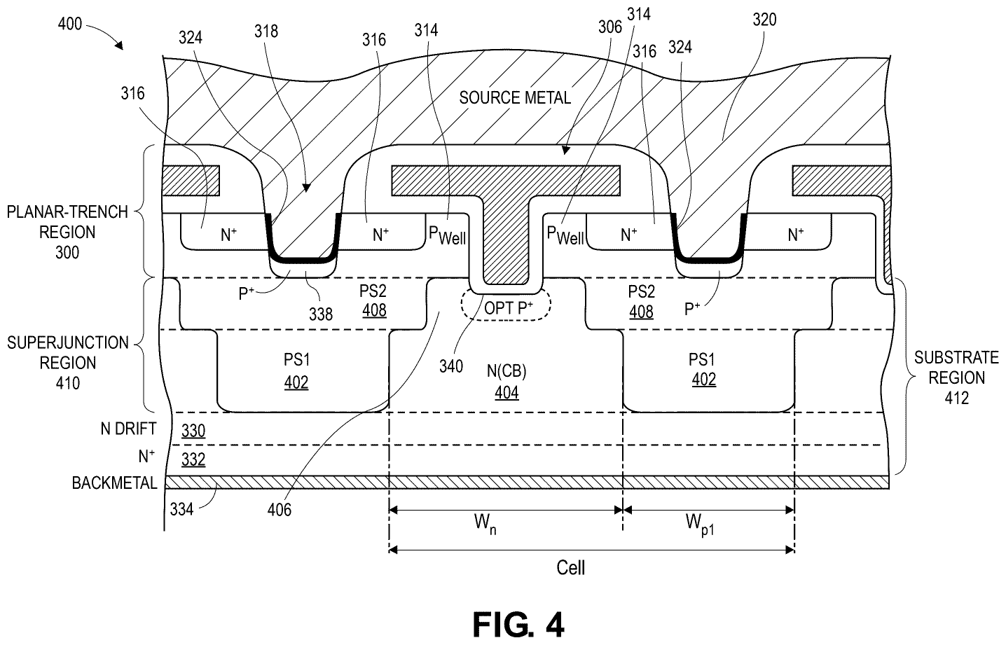

FIG. 4 depicts a simplified cross-sectional view of a portion of a SiC-based transistor 400, according to embodiments of the disclosure; in FIG. 4, like numbers reference like items relative to FIGS. 2-3. SiC-based transistor 400 is similar to SiC-based transistor 200 of FIGS. 2-3 but the SiC-based transistor 400 can include an additional P-doped region 402, which is labeled PS1 and can be referred to as a “P-type sinker #1 layer” or a “PS1” region, and N-doped charge-balance regions 404 can have narrower top regions 406 to accommodate PS2 regions 408 that can be wider than the PS1 regions and the PS2 regions 336 of FIG. 3. SiC-based transistor 400 otherwise may be the same as, or similar to, the SiC transistor 200 of FIGS. 2-3 in structure, operation, or both structure and operation. For example, the SiC-based transistor 400 may include any of the components, features, or characteristics of any of the embodiments of the SiC-based transistor 200 previously described. That is, the SiC transistor 400 can include one or more of the features of SiC-based transistor 200 as previously discussed in conjunction with FIGS. 2-3.

Still referring to FIG. 4, the PS1 regions 402 can be disposed beneath the PS2 regions 408 and can be formed by implantation with a controlled dose of a P-type impurity, such as aluminum or boron. The PS1 regions 402 can be buried under the N+ source regions 316 (and the PS2 regions 408) and can be electrically connected to, or otherwise in conductive coupling with, the P-well layer 314 and the PS2 regions. The PS1 regions 402 may be disposed at a greater depth than both the P-well layer 314 and the PS2 regions 408. Multiple PS1 regions 402 can alternate with the N-doped charge-balance regions 404 having a controlled dopant dose that is charge balanced with the dopant dose in the PS1 region 402 to form a superjunction region 410. By being disposed beneath the PS2 regions 408, the PS1 regions 402 can replace, effectively, the PS2 regions 336 in the superjunction region 304 of the transistor 200 of FIGS. 2-3. The superjunction region 410 of the SiC-based transistor 400 can have a same depth, or a different depth, than the superjunction region 304 of SiC-based transistor 200. Although as shown in FIG. 4 the widths of the PS1 regions 402, Wₚ₁, are shown to be less than the widths of the PS2 regions 408, the widths Wₚ₁ of the PS1 regions in the superjunction layer 410 can be equivalent to or different than the widths wₚ of the PS2 regions 336 in the superjunction layer 304 of the SiC-based transistor 200, and the widths of the N-doped charge-balance regions 404 can be adjusted as a result of a change in the widths of the PS1 regions 402 or of the PS2 regions 408. The doping level for the N-doped regions 404 in the superjunction layer 410 can be based on a charge-balancing condition with the PS1 regions 402 of the superjunction layer of the Si-C based transistor 400 in a manner similar to that described above in conjunction with the transistor 200 of FIGS. 2-3. Furthermore, the combination of a grouping of a P-well region 314, PS2 region 408, and PS1 region 402 can be considered to be a triple well that forms a superjunction pillar between the top of the SiC wafer and the N⁻ drift region 330.

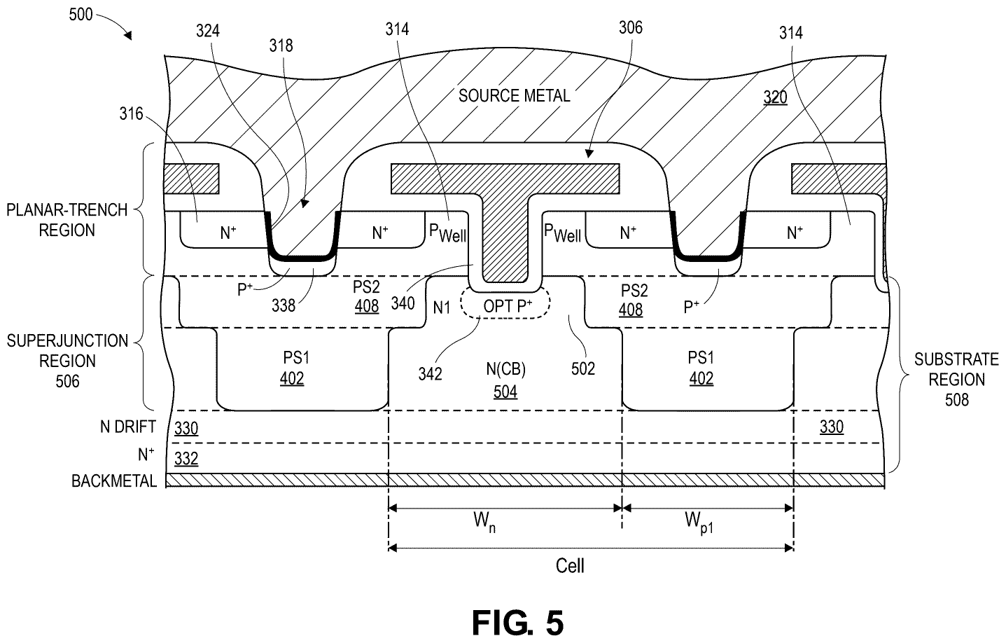

FIG. 5 depicts a simplified cross-sectional view of a portion of a SiC-based transistor 500, according to embodiments of the disclosure; in FIG. 5, like numbers reference like items relative to FIGS. 2-4. The SiC-based transistor 500 can be similar to the SiC-based transistors 200 of FIGS. 2-3 and to the SiC-based transistor 400 of FIG. 4, but the SiC-based transistor 500 can include additional N-doped regions 502 labeled “N1” and that are respectively positioned above each N-doped charge-balance region 504. The SiC-based transistor 500 otherwise may be the same as, or similar to, the SiC transistor 200 of FIGS. 2-3 or the SiC transistor 400 of FIG. 4 in structure, operation, or both structure and operation. That is, the SiC transistor 500 can include one or more of the components, features, or characteristics of any embodiments of the SiC-based transistors 200 or 400 previously described and as previously discussed.

Each N1 region 502 can have a same or different doping level than the N-doped regions 328 or 404 of the superjunction regions 304 and 410, respectively, of the SiC-based transistor 200 of FIGS. 2-3 or the SiC-based transistor 400 of FIG. 4. For example, the doping level of the N1 regions 502 can be equivalent to, greater than, or less than the doping level of the N drift layer 330 as described above. Or, the doping level of the N1 regions 502 can be higher than the N-doped charge-balance regions 404 of the transistor 400 of FIG. 4, and, therefore, can be higher than the N-doped charge-balance regions 504 of the transistor 500, to compensate for the higher doping of the optional P+buffer regions 342. The N1 regions 502 result in a superjunction region 506 that is different from the superjunction region 304 and 410 of FIGS. 3 and 4, respectively, and a substrate region 508 that is different from the substrate regions 302 and 412 of FIGS. 3 and 4, respectively.

Referring to FIGS. 2-5, in summary, the T-shaped gates 306, the superjunction 304 with only PS2 regions 336, the superjunction region 410 with the PS2 regions 408 shallower than the PS1 regions 402, the bifurcated source regions 316, or the combination or subcombination of the aforementioned features can allow a SiC transistor (e.g., transistor 200, 400, or 500) to have a thinner substrate region 302/506, and, therefore, to have a lower RdsON, for a given maximum blocking voltage (e.g., positive drain-to-source voltage when the transistor is “off”) as compared to a SiC transistor lacking one or more of these features.

Furthermore, although the transistors 200, 400, and 500 of FIGS. 2-5 are described as being N-channel transistors, corresponding P-channel transistors (the “duals” of the transistors 200, 400, and 500) with similar characteristics and operating parameters can be formed according to the principles disclosed herein.

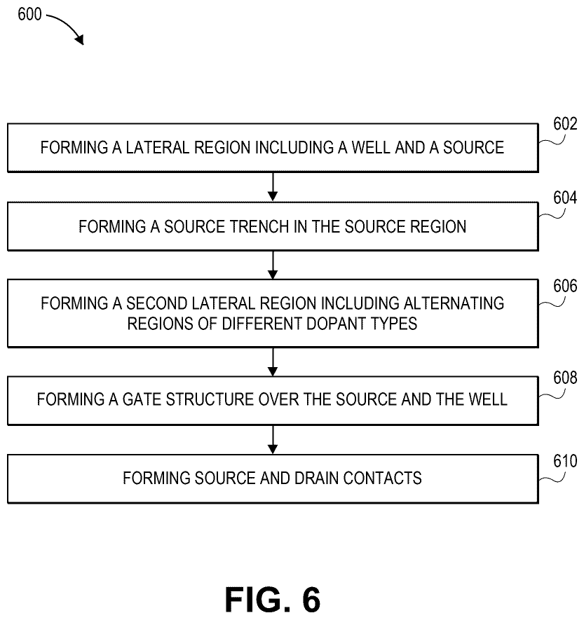

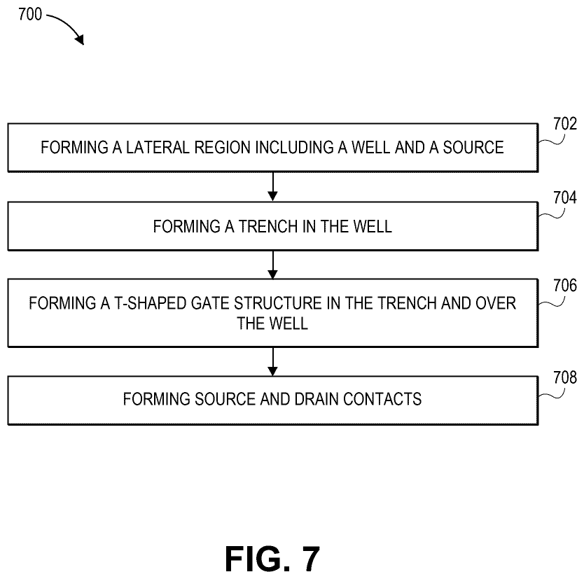

FIGS. 6 and 7 are flow diagrams 600 and 700, respectively, of respective processes for forming SiC transistors, according to one or more embodiments. At least some of the steps described in conjunction with FIGS. 6-7 can be used during the processing and manufacturing of one or more embodiments of the transistor 200 of FIGS. 2-3, the transistor 400 of FIG. 4, or transistor 500 of FIG. 5. Furthermore, one or more embodiments of the respective processes disclosed in conjunction with FIGS. 6-7 can include one or more steps that are the same as, or that are similar to, process steps disclosed in U.S. Pat. Nos. 10,916,632 or in 11,075,277, which are incorporated herein by reference. And the flow diagrams 600 and 700 may omit one or more steps that can be included in one or more embodiments of the respective processes or may include one or more steps that can be omitted from one or more embodiments of the respective processes.

FIG. 6 is a flow diagram 600, which includes steps in a process for forming a SiC transistor (e.g., transistor 400 of FIG. 4 or transistor 500 of FIG. 5) having at least one bifurcated source region (e.g., bifurcated source regions 316 of the transistor 400 of FIG. 4), a superjunction region (the superjunction region 410 of FIGS. 4-5), or both at least one bifurcated source region and a superjunction region, according to an embodiment.

At 602, a well (e.g., the P-well 314 of FIGS. 4-5) is formed in a drift region (e.g., N-drift region 330 of FIGS. 4-5) of a SiC wafer, and a source (e.g., N⁺ source 316 of FIGS. 4-5) is formed in the P-well, according to an embodiment. The wafer having a substrate region (e.g., N⁺ region 332 of FIG. 3) and the drift region disposed over the substrate may be provided, or, before 602, the drift region can be formed over the substrate via epitaxial growth and doping or any other suitable process. For example, the substrate, drift region, and source may have N-type conductivity, and the well may have P-type conductivity.

At 604, a source trench (e.g., the trench 318 of FIGS. 4-5) is formed in and through at least one region of the source (e.g., the source 316 of FIGS. 4-5); that is, the at least one region of the source is separated, i.e., bifurcated, into at least two regions by the forming of the source trench.

At 606, a lateral region (e.g., the superjunction region 410 of FIG. 4 or 506 of FIG. 5) with alternating subregions of different dopant types (e.g., P-type PS1 regions 402 and N-type charge-balance (CB) regions 404 of FIG. 4 or PS1 regions 402 and N-doped charge-balance regions 504 of FIG. 5) is formed beneath the well (e.g., P-well 314 of FIGS. 4-5) and the source trench (e.g., the trench 318 of FIGS. 4-5). For example, the lateral region may be a superjunction region (e.g., superjunction region 410 of FIG. 4 or 506 of FIG. 5).

At 608, which is optional as indicated by the dashed line, a gate structure (e.g., the gate structure 306 of FIGS. 4-5) is formed over the well (e.g., P-well 314 of FIGS. 4-5) and at least a portion of the source (e.g., source 316 of FIGS. 4-5; and although the gate structure 306 of FIGS. 4-5 is a T-shaped gate structure, the formed gate structure need not be T-shaped).

At 610, a source contact (e.g., the source metal 320 of FIGS. 4-5) is formed in the source trench (e.g., trench 318 of FIGS. 4-5) to contact the bifurcated source regions, and a drain contact (e.g., the back metal 334 of FIGS. 4-5) is formed over the back side of the substrate (e.g., the substrate 332 of FIGS. 4-5).

Still referring to FIG. 6, although the flow diagram 600 is described as including steps in an embodiment of a process for forming a SiC transistor having at least one bifurcated source region, a superjunction region, or both at least one bifurcated source region and a superjunction region, other steps that are omitted from the flow diagram can be included in the process to form the SiC transistor having other or additional features.

FIG. 7 is a flow diagram 700, which includes steps in a process for forming a SiC transistor having at least one bifurcated well region (e.g., bifurcated well regions 314 of the transistor 400 of FIG. 4 or of the transistor 500 of FIG. 5) and at least one T-shaped gate structure (e.g., the gate 306 of FIGS. 4-5), according to an embodiment.

At 702, a well (e.g., the P well 314 of FIGS. 4-5) is formed in a drift region (e.g., N⁻ drift region 330 of FIGS. 4-5) of a SiC wafer, and a source (e.g., N′ source 316 of FIGS. 4-5) is formed in the well, according to an embodiment. The well and the source can be considered to be part of a lateral region adjacent to a top surface of the wafer. The wafer having a substrate region (e.g., N⁺ region 332 of FIGS. 4-5) and the drift region disposed over the substrate may be provided, or, before 702, the drift region can be formed over the substrate by epitaxial growth and doping or by any other suitable process. For example, the substrate, drift region, and source may have N-type conductivity, and the well may have P-type conductivity.

At 704, a gate trench (e.g., the trench 340 of FIGS. 4-5) is formed in and through at least one region of the well (e.g., the well 314 of FIGS. 4-5); that is, each of the at least one region of the well is separated, i.e., bifurcated, into at least a respective two regions by the forming of the at least one trench.

At 706, a T-shaped gate structure (e.g., the T-shaped gate structure 306 of FIG. 4) is formed in the gate trench, over the regions of the well, and optionally over at least a portion of regions 316 of the source adjacent to the gate trench and the regions of the well.

And at 708, a source contact (e.g., the source metal 320 of FIGS. 4-5) is formed in contact with the regions 316 of the source and the regions 314 of the well, and a drain contact (e.g., the back metal 334 of FIGS. 4-5) is formed over the back side of the substrate (e.g., the substrate 332 of FIGS. 4-5).

Still referring to FIG. 7, although the flow diagram 700 is described as including steps in an embodiment of a process for forming a SiC transistor having at least one well region bifurcated with a trench and at least one gate at least partially formed in the trench, other steps that are omitted from the flow diagram can be included in the process to form the SiC transistor having other or additional features (e.g., a superjunction region or a bifurcated source).

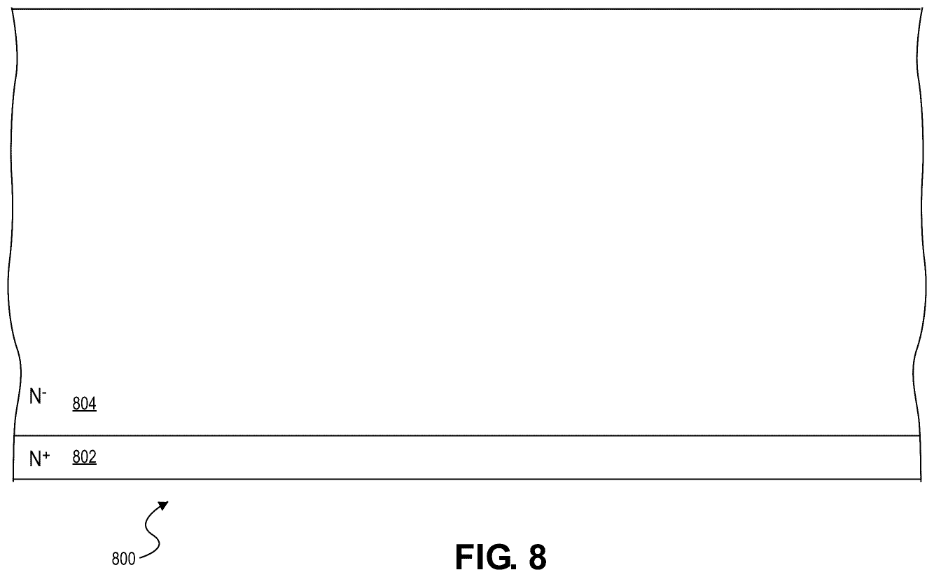

FIGS. 8-14 represent steps in a process for forming the transistor 500 of FIG. 5, according to an embodiment. Although FIGS. 8-14 represent steps in an embodiment of a process for forming the transistor 500, embodiments of processes for forming the transistor 200 of FIGS. 2-3 or the transistor 400 of FIG. 4, or for forming SiC transistors according to process embodiments described in conjunction with FIGS. 6-7, can include one or more of the steps represented by, and described in conjunction with, FIGS. 8-14. Furthermore, in one or more embodiments, one or more other steps that are unrepresented by FIGS. 8-14 can be included in the process to form the SiC transistor 500 having other or additional features, or one or more of the steps represented in FIGS. 8-14 may be omitted from a process for forming the transistor 500. In addition, the process steps represented by FIGS. 8-14 can be similar to process steps described in U.S. Pat. Nos. 10,916,632 or 11,075,277, which are incorporated herein by reference. And, in at least one embodiment, a process for forming the transistor 500 can include steps unrepresented by FIGS. 8-14 but described in U.S. Pat. Nos. 10,916,632 or 11,075,277.

Referring to FIG. 8, a SiC wafer 800 is provided having an N⁺ substrate 802 and an N⁻ drift region 804, according to an embodiment. Alternatively, the wafer 800 having only the N⁺ substrate 802 may be provided, and the N⁻ drift region 804 can be epitaxially grown, or otherwise suitably formed, over the substrate.

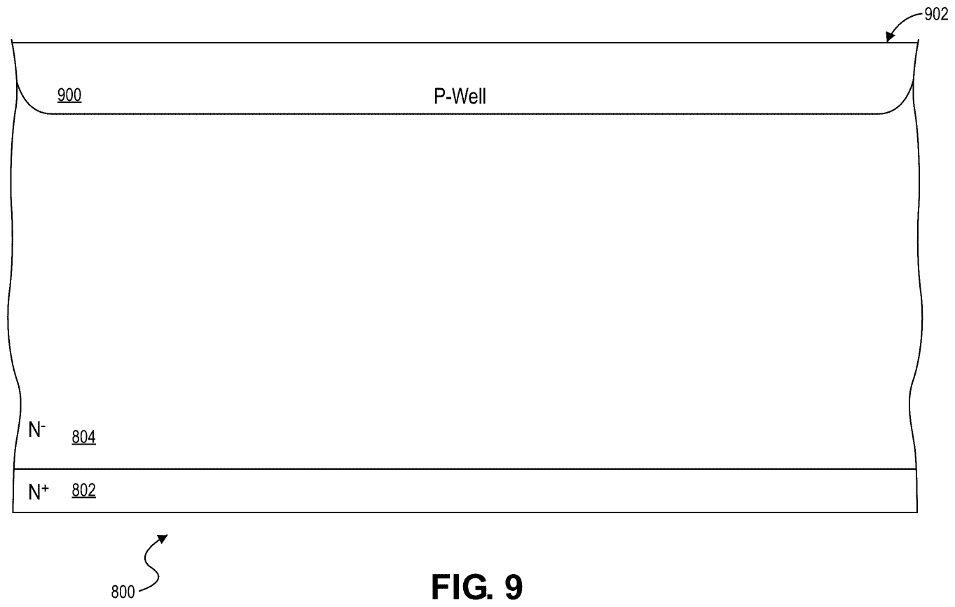

Referring to FIG. 9, a P-well 900 is formed in the N⁻ drift region 804 adjacent to an upper surface 902 of the SiC wafer 800, according to an embodiment. For example, the P-well 900 can be formed by forming and patterning a mask and then implanting a P-type dopant in the N⁻ drift region 804 (see, e.g., FIGS. 8b-8e of U.S. Pat. No. 10,916,632) followed by one or more annealing steps, which may occur immediately after the P-type-dopant implanting or after one or more subsequent process steps. Furthermore, the step 602 of the flow diagram 600 of FIG. 6 or the step 702 of the flow diagram 700 of FIG. 7 can include forming an N-well or a P-well in a similar manner.

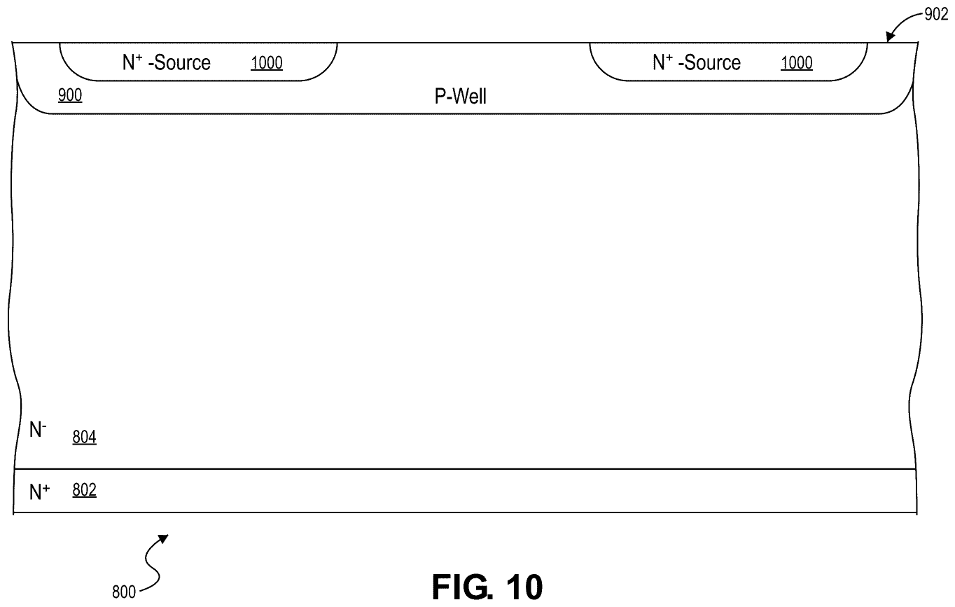

Referring to FIG. 10, one or more regions 1000 of an N⁺ source are formed in the P-well 900 adjacent to the upper surface 902 of the SiC wafer 800, according to an embodiment. For example, the one or more source regions 1000 can be formed by forming and patterning a mask (e.g., including forming sidewall spacers along the walls of the opening of the P-well mask used to form the P-well 900 and forming a mask in the middle of the P-well-mask opening so that the one or more source regions are self-aligned to the P-well) and then implanting an N-type dopant in the P-Well (see, e.g., FIGS. 8f-8g of U.S. Pat. No. 10,916,632) followed by one or more annealing steps, which may occur immediately after the N-type-dopant implanting or after one or more subsequent process steps. Furthermore, the step 602 of the flow diagram 600 of FIG. 6 or the step 702 of the flow diagram 700 of FIG. 7 can include forming an N source or P source in a similar manner.

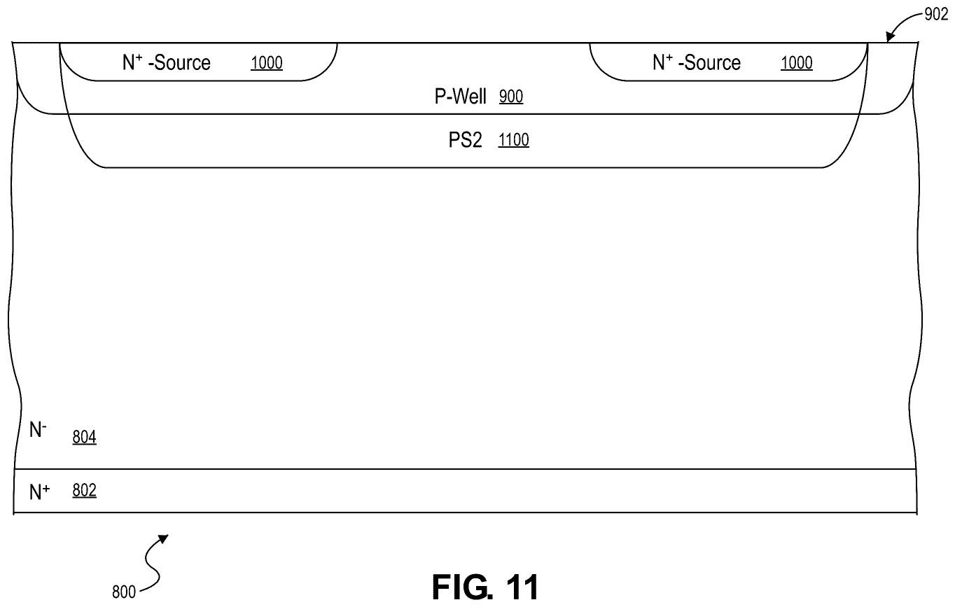

Referring to FIG. 11, one or more sinker regions PS2 1100 are formed in the N⁻ drift region 804 beneath the P-well 900 and are self-aligned to at least two of the N⁺ source regions 1000, according to an embodiment. For example, the one or more sinker regions PS2 1100 can be formed by implanting a P-type dopant using the same mask as used to form the one or more source regions 1000 (with any midportion of the mask used to generate the one or more spacings between the one or more source regions removed) so that the one or more sinker regions PS2 are self-aligned to the one or more source regions; the implanting of the P-type dopant can be at a high enough energy to drive the lower boundary of the one or more sinker regions PS2 deeper than the P-well 900 (see, e.g., FIGS. 8h-8i of U.S. Pat. No. 10,916,632) followed by one or more annealing steps, which may occur immediately after the P-type-dopant implanting or after one or more subsequent process steps. Furthermore, although not expressly included in FIGS. 6-7, the flow diagram 600 of FIG. 6 or the flow diagram 700 of FIG. 7 can include forming a P-type or N-type sinker region in a similar manner.

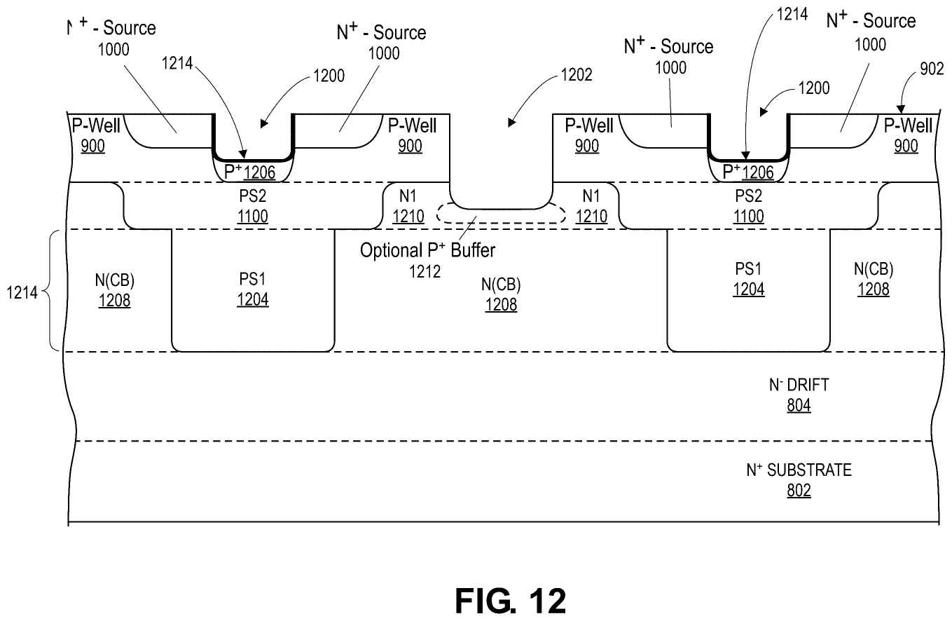

Referring to FIG. 12, one or more source trenches 1200 and one or more gate trenches 1202 are formed. Each source trench 1200 bisects, or bifurcates, a respective single region of the N⁺ source 1000 into at least two regions of the source (see, e.g., FIGS. 8j-8m of U.S. Pat. No. 10,916,632). Likewise, each gate trench 1202 bisects, or bifurcates, a respective single region of the P-well 900 into at least two regions of the P-well. The one or more source trenches 1200 and the one or more gate trenches 1202 can be formed in the same step or in different steps. Referring to the flow diagram 600 of FIG. 6, step 604′s “forming a trench in the source region” can be similar to the forming of the one or more source trenches 1200; likewise, referring to the flow diagram 700 of FIG. 7, step 704′s “forming a trench in the well” can be similar to the forming of the one or more gate trenches 1202.

Still referring to FIG. 12, sinker regions PS1 1204 (e.g., similar to the PS1 regions 402 of FIG. 5) are formed by a first implant of a P-type dopant through a mask that exposes each of the one or more source trenches 1200 (see, e.g., FIGS. 8n-8p of U.S. Pat. No. 10,916,632). By using the same mask as the mask used to form the one or more source trenches 1200, the sinker regions PS1 1204 can be self-aligned to the source trenches 1200. Furthermore, this first P-dopant implant may be high-energy so that the regions PS1 1204 are formed below the previously formed sinker regions PS2 1100. In addition, this first P-dopant implant may be angled so that each region PS1 1204 is formed to be wider than the source trench 1200 via which the respective PS1 sinker region 1204 is implanted.

Then, a second implant of a P-type dopant through the same mask can form P⁺ source-contact regions 1206 (e.g., similar to the P⁺ regions 338 of FIG. 5) in the PS2 sinker regions 1100 directly below the source trenches 1200. This second implant can be of lower energy than the first implant because the P+source-contact regions 1206 are significantly shallower than the sinker regions PS1 1204.

Likewise, N-doped charge-balance (N(CB)) regions 1208 (e.g., similar to the N(CB) regions 504 of FIG. 5) are formed by a first implant of an N-type dopant through a mask that exposes each of the one or more gate trenches 1202. By using the same mask as the mask used to form the one or more gate trenches 1202, the N-doped charge-balance regions 1208 can be self-aligned to the gate trenches 1202. Furthermore, this first implant may be relatively high-energy so that the N-doped charge-balance regions 1208 are formed at a same level as the sinker regions PS1 1204. In addition, this first N-dopant implant may be angled so that each N-doped charge-balance region 1208 is formed to be wider than the gate trench 1202 via which the respective N-doped charge-balance region is implanted.

Next, a second, lower-energy (e.g., shallower) implant of an N-type dopant through the same mask can form N1 regions 1210 (e.g., similar to the N1 regions 502 of FIG. 5), which can have a different doping level (e.g., typically higher, or lower) than the N (CB) regions 1208.

Then, a third implant of a P-type dopant through the same mask can form optional P+buffer regions 1212 (e.g., similar to the P⁺ buffer regions 342 of the transistor 500 of FIG. 5) at the bottoms of the one or more gate trenches 1202.

These implanting steps can be followed by one or more annealing steps, which may occur immediately after the third implant of the P-type-dopant or after one or more subsequent process steps.

Still referring to FIG. 12, the implanting of P-type and N-type dopants that form the PS1 1204 and N(CB) 1208 regions form a lateral region of alternating P-doped and N-doped regions (referring to the flow diagram 600 of FIG. 6, the step 606 can include the forming of alternating P-doped and N-doped regions as described in conjunction with FIG. 12); that is, the alternating PS1 and N(CB) regions form a superjunction region 1214 (e.g., similar to the superjunction region 506 of the transistor 500 of FIG. 5).

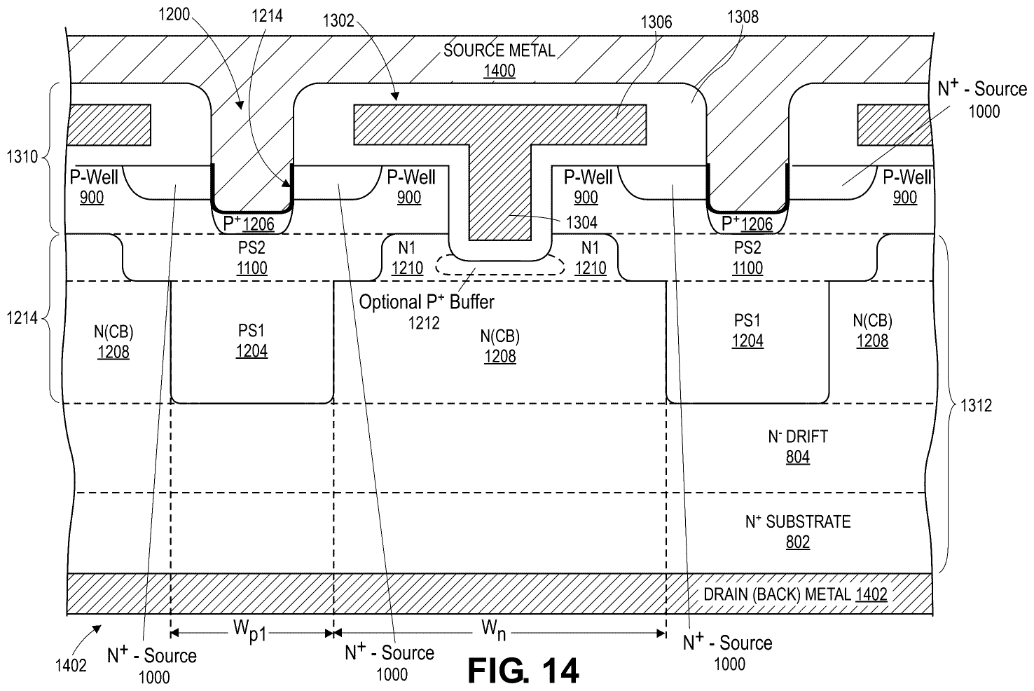

Next, silicide regions 1214 can be formed in each of the one or more source trenches 1200 to enhance electrical conduction between a to-be-formed source metal (see FIG. 14) and the N⁺ source regions 1000 and the P-well-contact regions 1206.

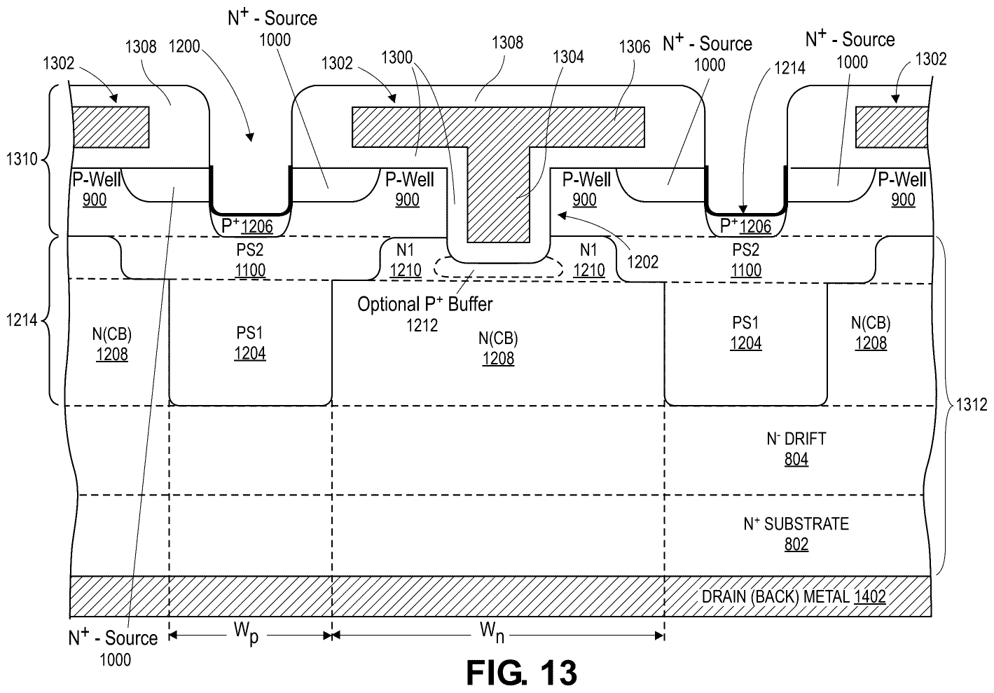

Referring to FIG. 13, a gate insulator 1300 is formed (e.g., patterned and etched) in and around the one or more gate trenches 1202.

Next, one or more T-shaped gates 1302 (e.g., similar to the T-shaped gate 306 of the transistor 500 of FIG. 5) are formed (e.g., patterned and etched) over the gate insulator 1300, each gate having a vertical section 1304 formed in the gate trench 1202 and having a lateral (horizontal) section 1306 formed over the gate insulator and extending over the P-well 900 and, optionally, over at least a portion of each adjacent region of the N⁺ source 1000. For example, the one or more T-shaped gates 1302 are formed by depositing polysilicon in the one or more gate trenches 1202 and over the other regions of the gate insulator 1300, then patterning the polysilicon with photoresist or in another suitable manner, and etching the polysilicon.

Then, an interlayer dielectric is deposited and patterned to form an insulator 1308 over the one or more gates 1302 and regions of the source 1000, but leaving the one or more source trenches 1200 open and the one or more silicide regions 1214 exposed.

Referring to the flow diagrams 600 and 700 of FIGS. 6-7, the steps 608 and 706 can include the forming of the gate insulator 1300, gates 1302, and insulator 1308 as described in conjunction with FIG. 13.

Still referring to FIG. 13, a lateral trench region 1310 extends vertically from the top of the N1 regions 1210 to the top of the insulator 1308, and a substrate region 1312 extends vertically from the bottom of the N⁺ substrate 802 to the top of the insulator 1308. As discussed above, for a given forward-blocking-voltage rating, the presence of the superjunction 1214 allows the substrate region 1312 to be thinner than it would need to be without the presence of the superjunction, and thus allows RdsON of the to-be-formed transistor to be lower than it would be in a comparable transistor that does not include the superjunction.

Referring to FIG. 14, a source metal 1400 is formed in the source trenches 1200 and over the insulator 1308, and a drain metal 1402 (e.g., a back metal) is formed on the exposed side of the N⁺ substrate 802 to form an N-channel transistor 1402 having external source and drain contacts (e.g., the source and drain metals); for example, the transistor 1402 can be the same as, or similar to, the transistor 500 of FIG. 5. The silicide regions 1214 can decrease the resistance, e.g., enhance the electrical conduction, between the source metal 1400 and the regions of the N′ source 1000 and the regions of the P-well 900.

Referring to the flow diagrams 600 and 700 of FIGS. 6-7, the steps 610 and 708 can include the forming of the source metal 1400 and the drain metal 1402 as described in conjunction with FIG. 14.

Still referring to FIG. 14, although described as forming an N-channel SiC transistor, in an embodiment one can modify the process described in conjunction with FIGS. 8-14 to form a P-channel SiC transistor according to the principle of duality.

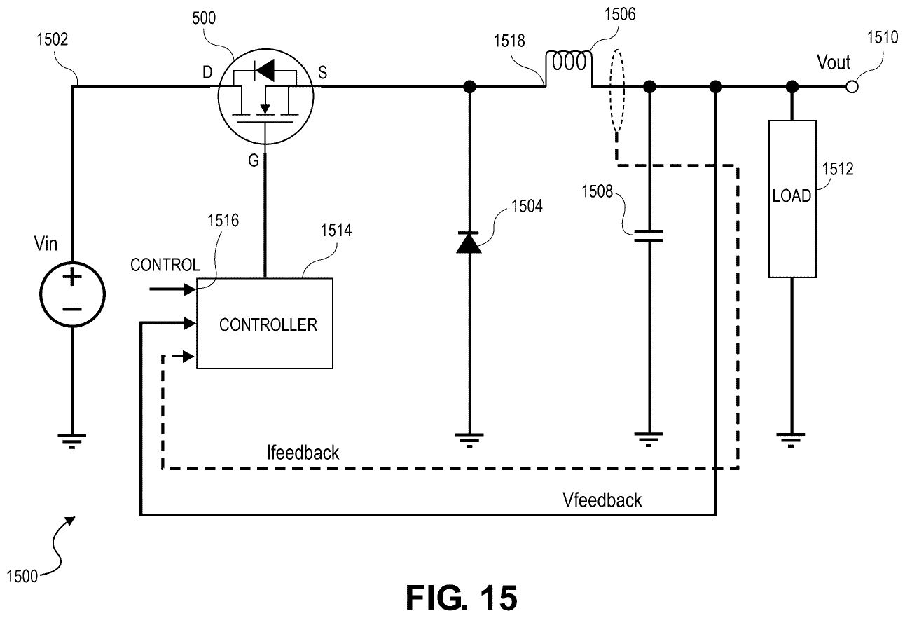

FIG. 15 is a schematic diagram of a power supply, here a buck converter, 1500 that can incorporate one of the SiC N-channel transistors 200, 400, 500, or 1402 of FIGS. 2-5 and 14, according to an embodiment (for clarity, the buck converter is described as incorporating a single SiC N-channel transistor 500, it being understood that the operation of the buck converter is comparable if incorporating one of the SiC transistors 200, 400, or 1402).

In addition to the SiC transistor 500, the buck converter 1500 includes a voltage-input node 1502 configured for receiving an input DC voltage Vᵢₙ, a circulation diode or other unidirectional device 1504, at least one inductor 1506, a filter capacitor 1508, a voltage-output node 1510 configured for providing a regulated output voltage Vₒᵤₜ to a load 1512, and a controller 1514 configured for driving (e.g., switching) the SiC transistor.

In operation, at a control node 1516, the controller 1514 receives an analog or digital control signal that configures the controller to regulate Vₒᵤₜ to a particular value, for example 1.10 Volts (V).

During a first part of a switching cycle, the controller 1514 drives the transistor 500 to a conducting, or “on,” state. In response to the transistor 500 being “on,” and assuming that the voltage drop across the drain-source junction of the transistor is low enough to be negligible for purposes of this description, the transistor effectively couples the input voltage Vᵢₙ to a node 1518 of the inductor 1506. Because Vᵢₙ (e.g., 5.0 V) is higher than Vₒᵤₜ, an increasing (ramping) current flows from the source(S) of the transistor 500, through the inductor 1506, and into both the capacitor 1508 and the load 1512 (this assumes that the impedances of the V_{feedback} and I_{feedback} nodes of the controller 1514 are very high), where the slope of the current increase is (Vᵢₙ-Vₒᵤₜ)/L, where L is the inductance of the inductor.

At some time after the controller 1514 turns the transistor 500 “on,” the increasing current flowing out from the inductor 1506 into the capacitor 1508 and the load 1512 exceeds the current flowing into the load 1512. At this time, some of the current output by the inductor 1506 flows into the filter capacitor 1508, thus increasing the charge on the capacitor and causing the output voltage, Vₒᵤₜ, across the filter capacitor and the load 1512 to begin increasing in a ramping fashion (this increasing and decreasing (described below) of Vₒᵤₜ is often called the “output ripple voltage” or something similar).

Vₒᵤₜ, or a derivative thereof, is fed back to the controller 1514 as feedback voltage V_{feedback}. In response to V_{feedback} exceeding a threshold voltage set by the control signal at the control node 1516, the controller 1514 drives the transistor 500 into a nonconducting, or “off,” state in which the transistor sources little to no (e.g., negligible) current to the inductor 1506.

In response to the turn “off” of the transistor 500, a decreasing (e.g., ramping down) current (sometimes called a “circulating current”) flows from ground, through the diode 1504 and the inductor 1506, and into the capacitor 1508 and the load 1512, where the slope of the current decrease is—(Vₒᵤₜ+V_{diode})/L and V_{diode} is the forward-voltage drop across the diode.

In response to this ramping-down inductor current becoming less than the current being drawn by the load 1512 (i.e., the “load current”), the capacitor 1508 sources, to the load, the difference between the inductor current and the load current, and Vₒᵤₜ begins to ramp downward.

In response to Vₒᵤₜ, and thus V_{feedback}, becoming less than the threshold voltage set by the control signal at the control node 1516, the controller 1514 turns the transistor 500 “on” again, and the above-described switching cycle repeats.

The controller 1514 also can employ optional feedback of the current through the inductor 1506 via a feedback signal I_{feedback}, which can be a voltage or a current, in addition to the output-voltage feedback signal V_{feedback}. The controller 1514 turns the transistor 500 “on” and “off” in response to both I_{feedback} and V_{feedback}. Using current feedback can allow the controller 1514 to respond more rapidly to a load transient than using voltage feedback alone.

Still referring to FIG. 15, alternate embodiments of the power supply 1500 are contemplated. For example, instead of being a buck converter having the single-phase topology described, the power supply 1500 may be a buck converter having a multi-phase topology in which the buck converter incorporates multiple SiC transistors 200, 400, 500, or 1402 and multiple inductors 1506 (the inductors can be magnetically coupled to one or more of the other inductors, or magnetically uncoupled from all of the other inductors). Or, the power supply 1500 can be another type of power supply, such as a boost converter, buck-boost converter, or flyback converter.

Referring to FIGS. 2-5, and 14-15, although described as being incorporated in a power supply 1500, one or more of the transistors 200, 300, 500, and 1402 can be incorporated in other electronic circuits and systems. Furthermore, although described as incorporating an N-channel SiC transistor, an electronic circuits and systems can incorporate a P-channel SiC transistor using the known principle of duality.

The following are additional Example embodiments.

Example 1: A silicon-carbide based transistor comprising:
a part-planar, part-trench channel region disposed on a silicon-carbide substrate and including a T-shaped gate region;
a source metal disposed on the planar-trench region and forming a source terminal of the transistor; and
a back metal disposed on a bottom surface of the substrate region and forming a drain terminal of the transistor.

Example 2: The silicon-carbide based transistor of Example 2 further comprising a first p-well region positioned adjacent a first vertical surface and a first horizontal surface of the T-shaped gate region, and a second p-well region positioned adjacent a second vertical surface and a second horizontal surface of the T-shaped gate region.

Example 3: The silicon-carbide based transistor of any of Examples 1-2 wherein a voltage bias between the T-shaped gate region and the source terminal forms an L-shaped channel region in each respective p-well region.

Example 4: The silicon-carbide based transistor of any of Examples 1-3 wherein a positive voltage bias applied to the drain terminal while the source terminal is coupled to ground generates a depletion region between each of the p-doped regions and the n-doped regions.

Example 5: The silicon-carbide based transistor of any of Examples 1-4, wherein the silicon-carbide substrate comprises a superjunction structure of alternating p-type doped regions and n-type doped regions arranged vertically.

Example 6: A silicon-carbide (SiC) transistor comprising: a layer of metallization forming a drain terminal of the transistor; and a SiC substrate, comprising:
a first generally horizontal N-type region disposed above the layer of metallization and including an N-type dopant;
a second generally horizontal P-well disposed above the N-type region and including a P-type dopant, wherein the P-well is bifurcated into a first P-well region and a second P-well region; and
a T-shaped polysilicon gate structure including a vertical portion disposed between the first and the second P-well regions and including a horizontal portion disposed above each of the first and the second P-well regions.

Example 7: The silicon-carbide transistor of Example 6, further comprising an electrically insulative material disposed between the T-shaped polysilicon gate structure and the P-well.

Example 8: The silicon-carbide transistor of any of Examples 6-7, further comprising a generally horizontal superjunction region disposed between the first generally horizontal N-type region and the second generally horizontal P-well region and including alternating P-type doped regions and N-type doped regions.

Terms such as “top”, “bottom”, “up”, or “down” are used herein for illustrative purposes only and do not indicate an absolute orientation of any component or part thereof. For example, a substrate of a power device is herein sometimes referred to as a bottom surface, regardless of an overall orientation of a transistor device. Similarly, a side of the power device that is on an opposite side of such a bottom surface, and therefore faces away from the substrate, is sometimes herein referred to as a top surface, again only indicating an orientation relative to the substrate of the transistor device. The terms up and down are used in a similar sense herein.

The specification and drawings are, accordingly, to be regarded in an illustrative rather than a restrictive sense. It will, however, be evident that various modifications and changes may be made thereunto without departing from the broader spirit and scope of the disclosure as set forth in the claims.

Other variations are within the spirit of the present disclosure. Thus, while the disclosed techniques are susceptible to various modifications and alternative constructions, certain illustrated embodiments thereof are shown in the drawings and have been described above in detail. It should be understood, however, that there is no intention to limit the disclosure to the specific form or forms disclosed, but on the contrary, the intention is to cover all modifications, alternative constructions and equivalents falling within the spirit and scope of the disclosure, as defined in the appended claims.

The use of the terms “a” and “an” and “the” and similar referents in the context of describing the disclosed embodiments (especially in the context of the following claims) are to be construed to cover both the singular and the plural, unless otherwise indicated herein or clearly contradicted by context. The terms “comprising,” “having,” “including,” and “containing” are to be construed as open-ended terms (i.e., meaning “including, but not limited to,”) unless otherwise noted. The term “connected” is to be construed as partly or wholly contained within, attached to, or joined together, even if there is something intervening. The phrase “based on” should be understood to be open-ended, and not limiting in any way, and is intended to be interpreted or otherwise read as “based at least in part on,” where appropriate. Recitation of ranges of values herein are merely intended to serve as a shorthand method of referring individually to each separate value falling within the range, unless otherwise indicated herein, and each separate value is incorporated into the specification as if it were individually recited herein. All methods described herein can be performed in any suitable order unless otherwise indicated herein or otherwise clearly contradicted by context. The use of any and all examples, or exemplary language (e.g., “such as”) provided herein, is intended merely to better illuminate embodiments of the disclosure and does not pose a limitation on the scope of the disclosure unless otherwise claimed. No language in the specification should be construed as indicating any non-claimed element as essential to the practice of the disclosure.

Disjunctive language such as the phrase “at least one of X, Y, or Z,” unless specifically stated otherwise, is otherwise understood within the context as used in general to present that an item, term, etc., may be either X, Y, or Z, or any combination thereof (e.g., X, Y, and/or Z). Thus, such disjunctive language is not generally intended to, and should not, imply that certain embodiments require at least one of X, at least one of Y, or at least one of Z to each be present. Additionally, conjunctive language such as the phrase “at least one of X, Y, and Z,” unless specifically stated otherwise, should also be understood to mean X, Y, Z, or any combination thereof, including “X, Y, and/or Z.”

Preferred embodiments of this disclosure are described herein, including the best mode known to the inventors for carrying out the disclosure. Variations of those preferred embodiments may become apparent to those of ordinary skill in the art upon reading the foregoing description. The inventors expect skilled artisans to employ such variations as appropriate, and the inventors intend for the disclosure to be practiced otherwise than as specifically described herein. Accordingly, this disclosure includes all modifications and equivalents of the subject matter recited in the claims appended hereto as permitted by applicable law. Moreover, any combination of the above-described elements in all possible variations thereof is encompassed by the disclosure unless otherwise indicated herein or otherwise clearly contradicted by context.

All references, including publications, patent applications, and patents, cited herein are hereby incorporated by reference to the same extent as if each reference were individually and specifically indicated to be incorporated by reference and were set forth in its entirety herein.

What is claimed is:

1. A silicon-carbide (SiC) transistor, comprising:
a layer of metallization forming a drain terminal of the transistor; and
a SiC substrate disposed above the layer of metallization and comprising:
a first generally horizontal region disposed above the layer of metallization and including an N-type dopant;
a second generally horizontal region disposed above the first generally horizontal region and including an N-type doped region disposed beside a P-type doped region;
a gate structure including a gate conductor disposed above the N-type doped region; and
a source including an N-type dopant, disposed above the P-type doped region, and bisected by a source metal electrically coupled to the P-type doped region.

2. The SiC transistor of claim 1, wherein the second generally horizontal region includes a plurality of alternating N-type doped regions and P-type doped regions.

3. The SiC transistor of claim 1, further comprising:
a P-well disposed above the second generally horizontal region; and
wherein the source is disposed in the P-well.

4. The SiC transistor of claim 3, wherein the gate structure:
includes polysilicon; and bisects the P-well.

5. The SiC transistor of claim 4, wherein the gate structure has a T-shape and includes: a vertical region that bisects the P-well into at least two regions; and a horizontal region integral with the vertical region and disposed above the at least two regions of the P-well.

6. A silicon-carbide (SiC) based transistor, comprising:
a layer of drain metal; and
a SiC-based substrate disposed above the layer of drain metal and comprising:
a first planar region including an N-type dopant;
a second planar region disposed above the first planar region and including alternating N-type doped regions and P-type doped regions arranged in a horizontal repeating pattern;
a plurality of P-well regions each disposed above a respective one of the N-type doped regions;
a plurality of source regions including an N-type dopant and each disposed above a respective one of the P-type doped regions; and
a layer of source metal bisecting each of the plurality of source regions.

7. The SiC-based transistor of claim 6, wherein at least some of the plurality of source regions are each disposed above a respective one of the plurality of P-well regions.

8. The SiC-based transistor of claim 6, further comprising at least one polysilicon gate structure each of which bifurcates a respective P-well region of the plurality of P-well regions.

9. The SiC-based transistor of claim 8, wherein each of the at least one polysilicon gate structure has a respective T-shaped cross-section including a respective vertical portion that bifurcates the respective P-well region and a respective horizontal portion disposed over portions of the respective bifurcated P-well region.

10. The SiC-based transistor of claim 6, wherein the drain metal includes multiple layers of metal.

11. A method for forming a silicon-carbide (SiC) transistor, the method comprising:
forming, over a first side of a first generally horizontal N-type region of a SiC substrate, a metal drain terminal;
forming, over a second side of the first generally horizontal N-type region that is opposite to the first side, a second generally horizontal region including a laterally arranged N-doped region and a P-doped region;
forming, over the P-doped region, a source region including an N-type dopant;
forming, through the source region, a source trench that exposes the P-doped region and includes vertical sides of the source trench that are disposed within the source region; and
forming, in the source trench, a source metal that electrically contacts the P-doped region and the vertical sides of the source region.

12. The method of claim 11, further comprising forming the first generally horizontal N-type region of the SiC substrate.

13. The method of claim 11, further comprising forming a gate conductor over the N-doped region.

14. The method of claim 11, wherein forming the second generally horizontal region comprises: forming a plurality of N-doped regions including the N-doped region; and forming a plurality of P-doped regions, including the P-doped region, that alternate with the N-doped regions.

15. The method of claim 11, further comprising: forming a P-well region over the second generally horizontal region; and
wherein forming the source region includes forming the source region in the P-well region.

16. The method of claim 15, further comprising: forming, through the P-well region, a gate trench that extends into the N-doped region; and
forming, in the gate trench, a polysilicon gate that extends laterally over the P-well region.

17. The method of claim 15, further comprising, forming a T-shaped polysilicon gate having a vertical region that bisects the P-well region into at least two regions and having a horizontal region integral with the vertical region and disposed over the at least two regions of the P-well region.

18. The method of claim 16, wherein the N-doped region is a first N-doped region, the method further comprising forming a second N-doped region between the first N-doped region and a bottom of the gate trench.

19. The method of claim 18, further comprising forming a second P-doped region in the second N-doped region at a bottom of the gate trench.

20. The method of claim 11, wherein the P-doped region is a first P-doped region, the method further comprising forming a second P-doped region between the first P-doped region and a bottom of the source trench.
